(19) United States
(12) Patent Application Publication
(10) Pub. No.: US 2006/0027324 A1
(43) Pub. Date: Feb. 9, 2006

(54) Plasma processing apparatus and plasma processing method

(76) Inventors: Akitaka Makino, Hikari-shi (JP); Koichi Mishima, Tokyo (JP); Takashi Kaneko, Shiroi-shi (JP); Toyoharu Okumoto, Hitachinaka-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/068,805

(22) Filed: Mar. 2, 2005

(30) Foreign Application Priority Data
Aug. 3, 2004 (JP) 2004-226959

(51) Int. Cl. H01L 21/306; G01L 21/30

(52) U.S. Cl. 156/345.24; 216/60

(57) ABSTRACT

The present invention provides a plasma processing apparatus that can accomplish fine and precise processing of a sample over a wide area of the surface thereof. A plasma processing apparatus 100 has a processing chamber 101, a sample stage 102 that is supplied with different amounts of coolants at the middle part and the circumference part thereof, and a shower plate 109 that is supplied with different amounts of gases at the middle part and the circumference part thereof. The plasma processing apparatus 100 further has a light-receiving section 125 that receives plasma light emission in the processing chamber 101, a light emission spectrometer 124, a mass spectrometer 129 that analyzes the mass of a gas in a lower space of the processing chamber and a control device 130 and controls flow controllers 120, 121 for controlling the flow rates of the gases supplied into the processing chamber and a coolant flow controller 131 for controlling the flow rates of the coolants supplied to the sample stage 102 using both the data about the light emission analysis and the mass analysis.

The present application is based on and claims priority of Japanese patent application No. 2004-226959 filed on Aug. 3, 2004, the entire contents of which are hereby incorporated by reference.

### BACKGROUND OF THE INVENTION

1. Field of the Invention

The present invention relates to a plasma processing apparatus that produces a plasma in a vessel and processes a sample placed in the vessel using the plasma, and a plasma processing method therefor. In particular, it relates to a plasma processing apparatus that processes a film formed on a surface of a sample and a plasma processing method therefor.

2. Description of the Related Art

To achieve higher densities of semiconductor devices, plasma processing apparatus of this type are required to have still more refined process capabilities. For example, in the formation of a gate in a film on a surface of a sample by etching or other process, the amount of the film etched, the width of the resulting gate and the depth of the resulting groove are desirably small, and therefore, there is a need for a technique of forming such elements with high precision.

To achieve such refined or precise machining, the interaction between the plasma and the sample at the sample surface has to be precisely controlled. Conventionally, it has been common practice to adjust the plasma itself or the operation of the sample stage.

According to conventional known techniques, for example, the distribution of the reactive gas introduced for forming the plasma or the distribution of the intensity of the electromagnetic wave introduced into the vessel is adjusted, or the temperature distribution of the sample stage on which the sample is mounted or the temperature distribution of the sample surface is adjusted to adjust the interaction between the sample surface and substances in the plasma.

As an exemplary conventional art, there has been known a processing apparatus that has a processing chamber, which is a vacuum vessel, a wafer mounting table in the processing chamber and an opposite electrode located above and facing the wafer mounting table and processes a wafer using a plasma of a gas introduced into the processing chamber, the plasma being produced by a electric wave supplied to the wafer mounting table. The processing apparatus further has a light emission spectroscopic detector attached to the processing chamber for detecting light emission of the plasma and determines the end point of the processing based on the detection result (see Japanese Patent Application Laid-Open Publication No. 2001-250812, hereinafter referred to as prior art 1). In particular, the processing apparatus disclosed in this prior art 1 is one that detects a variation of a mass spectrum of a predetermined constituent of the gas in the processing chamber using a mass spectrometer, thereby determining the end point of the processing more precisely based on the detection results of the mass spectrometer and the light emission spectroscopic detector.

However, the conventional technique described above will not be able to adequately control the processing as still more refined process is required.

According to the conventional technique described above, the precision of the determination of the end point of the processing is enhanced by using, in a complementarily cooperative manner, information about the end point of the processing at a particular condition derived from a variation of an emission spectrum of a radicals at the particular position or condition and information about the end point of the processing derived from a mass spectrum of the whole gas in the chamber. In other words, while the conventional technique described above can detect the end point of the processing at a plurality of particular positions or detect the end point of the processing as a representative value for the entire chamber, the technique does not allow for adjustment of the processing based on the distribution of an interaction or reaction between the plasma and a wide area of the wafer surface.

In addition, the light emission spectrum can provide information about a particular substance that emits light but cannot provide information about other substances. On the other hand, the mass spectrometer can provide information about many kinds of substances including ones that emit no light but cannot provide information about a particular position in the chamber. Thus, the processing of the surface of a large wafer can not be accomplished in precise enough.

Furthermore, the partial pressures of each kinds of gases consisting of the process gas in the processing chamber in which the reaction proceeds differ from the partial pressures of the plural kinds of gases of the process gas supplied. Therefore, in order to precisely adjust the processing of the sample surface, the condition in the processing chamber or of the sample surface has to be detected during the actual processing, and the operations of operating sections of the apparatus has to bead justed based on the result of the detection. However, the conventional technique does not take into account of these as mentioned above.

### SUMMARY OF THE INVENTION

An object of the present invention is to provide a plasma processing apparatus that can accomplish fine and precise processing over a wide area of the surface of a sample, such as a semiconductor wafer, and a plasma processing method therefor.

To attain the object described above, the present invention provides a plasma processing apparatus that has a processing chamber to be decompressed, a sample stage which is disposed in the processing chamber and on which a sample to be processed is mounted, and a supply hole for supplying a process gas into the processing chamber from above the sample stage and processes the sample using a plasma produced from the process gas in the processing chamber, the plasma processing apparatus comprising: a light emission spectrometer that receives light emission of the plasma and detects a constituent of the plasma; a mass spectrometer that takes in a gas in the processing chamber and determines the mass of a constituent of the gas; and a control device that adjusts the operation of the plasma processing apparatus based on the output of the light emission spectrometer and the output of the mass spectrometer.

In addition, according to the present invention, in the plasma processing apparatus, the control device adjusts at least one of the supply of the process gas into the processing chamber, the temperature of a coolant supplied into the sample stage, the pressure of a heat-transferring gas supplied between the sample and the sample stage, and the power supplied to an electrode provided on the sample stage.

The present invention provides a plasma processing apparatus that has a processing chamber to be decompressed, a sample stage which is disposed in the processing chamber and on which a sample to be processe dismounted, a plate disposed above the sample stage, and two supply holes formed in the plate at positions close to the middle and the circumference of the processing chamber for supplying different kinds of process gases into the processing chamber and processes the sample using a plasma produced from the process gases in the processing chamber, the plasma processing apparatus comprising: a light emission spectrometer that receives light emission of the plasma and detects a constituent of the plasma; amass spectrometer that takes in a gas in the processing chamber and determines the mass of a constituent of the gas; and a control device that adjusts the supply of the process gases through the two supply holes based on the output of the light emission spectrometer and the output of the mass spectrometer.

To attain the object described above, the present invention provides a plasma processing method for processing a sample by mounting the sample to be processed on a sample stage disposed in a processing chamber to be decompressed, supplying a process gas into the processing chamber, and producing a plasma in the processing chamber, the plasma processing method comprising: a step of adjusting the processing of the sample based on a result of receiving light emission of the plasma and detecting a light-emitting constituent of the plasma and a result of taking in a gas in the processing chamber and determining the mass of a constituent of the gas.

According to the present invention, the plasma processing method described above further comprises: a step of determining the distribution of the constituent of the plasma over the surface of the sample based on the result of the detection of the light-emitting constituent of the plasma and the result of the determination of the mass of the constituent of the gas in the processing chamber; and a step of adjusting the processing of the sample based on the detected distribution.

According to the present invention, in the plasma processing method described above, the processing of the sample is adjusted by adjusting at least one of the supply of the process gas into the processing chamber, the temperature of a coolant supplied into the sample stage, the pressure of a heat-transferring gas supplied between the sample and the sample stage, and the power supplied to an electrode provided on the sample stage.

To attain the object described above, the present invention provides a plasma processing method for processing a sample by mounting the sample to be processed on a sample stage disposed in a processing chamber decompressed, supplying different kinds of process gases into the processing chamber from above the sample stage at positions close to the middle and the circumference, and producing a plasma in the processing chamber, the plasma processing method comprising: a step of, based on a result of receiving light emission of the plasma and detecting a light-emitting constituent of the plasma and a result of taking in a gas in the processing chamber and determining the mass of a constituent of the gas, determining the distribution of the constituent of the plasma over the surface of the sample; and a step of adjusting the supply of the different kinds of process gases into the processing chamber.

### BRIEF DESCRIPTION OF THE DRAWINGS

FIG. 1 is a schematic vertical cross-sectional view of a plasma processing apparatus according to an embodiment of the present invention;

FIG. 2 is a schematic enlarged vertical cross-sectional view of a sample stage, and the periphery thereof, of the plasma processing apparatus shown in FIG. 1;

FIG. 3 is a schematic block diagram for illustrating an operation of the plasma processing apparatus according to the embodiment shown in FIG. 1; and

FIG. 4 is a flowchart illustrating an operation of the plasma processing apparatus shown in FIG. 1.

### DETAILED DESCRIPTION OF THE PREFERRED EMBODIMENTS

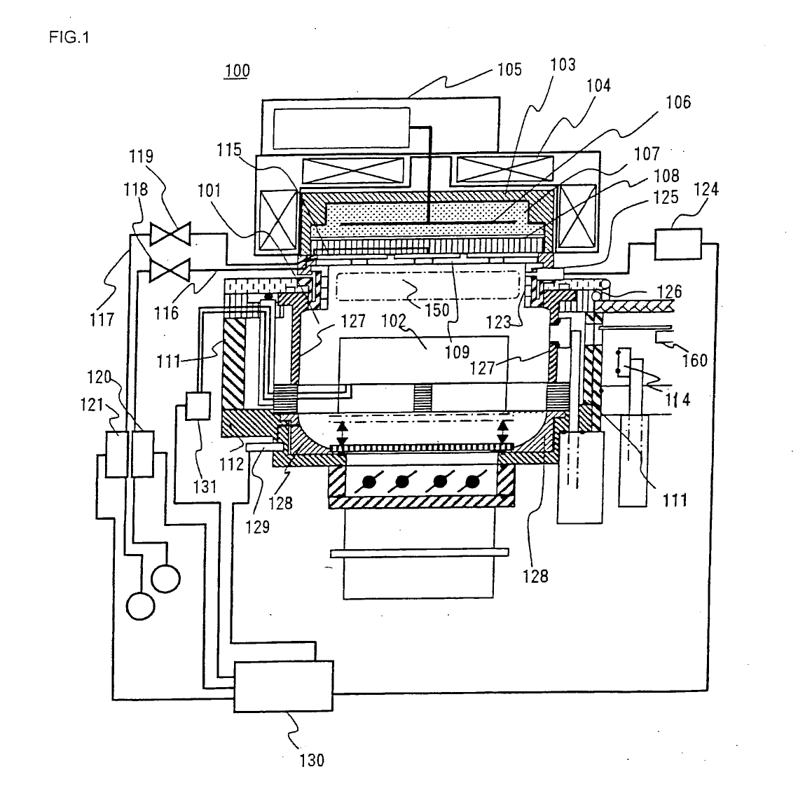

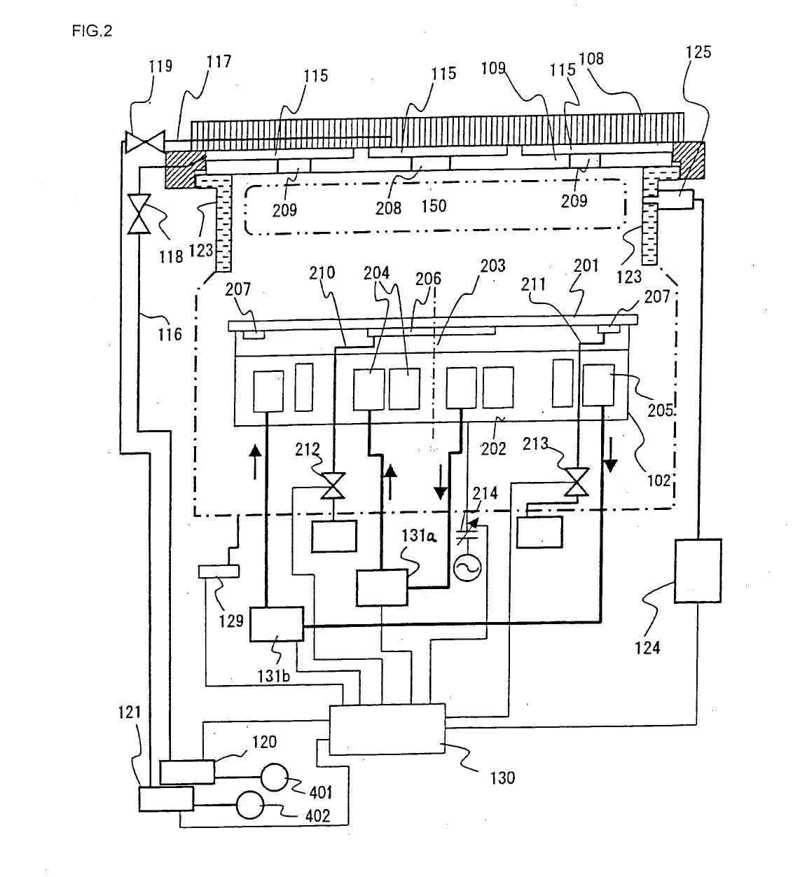

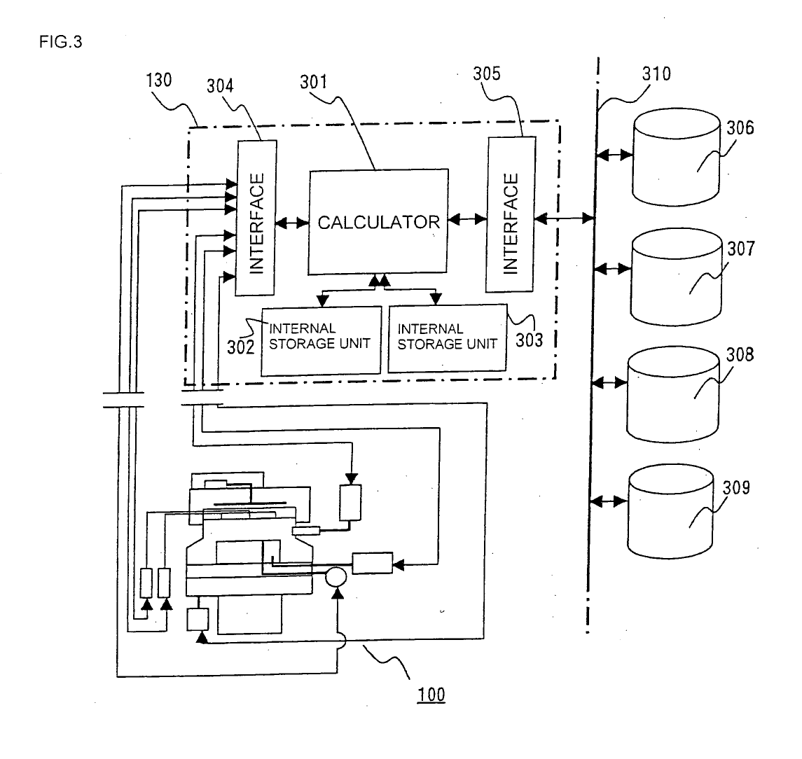

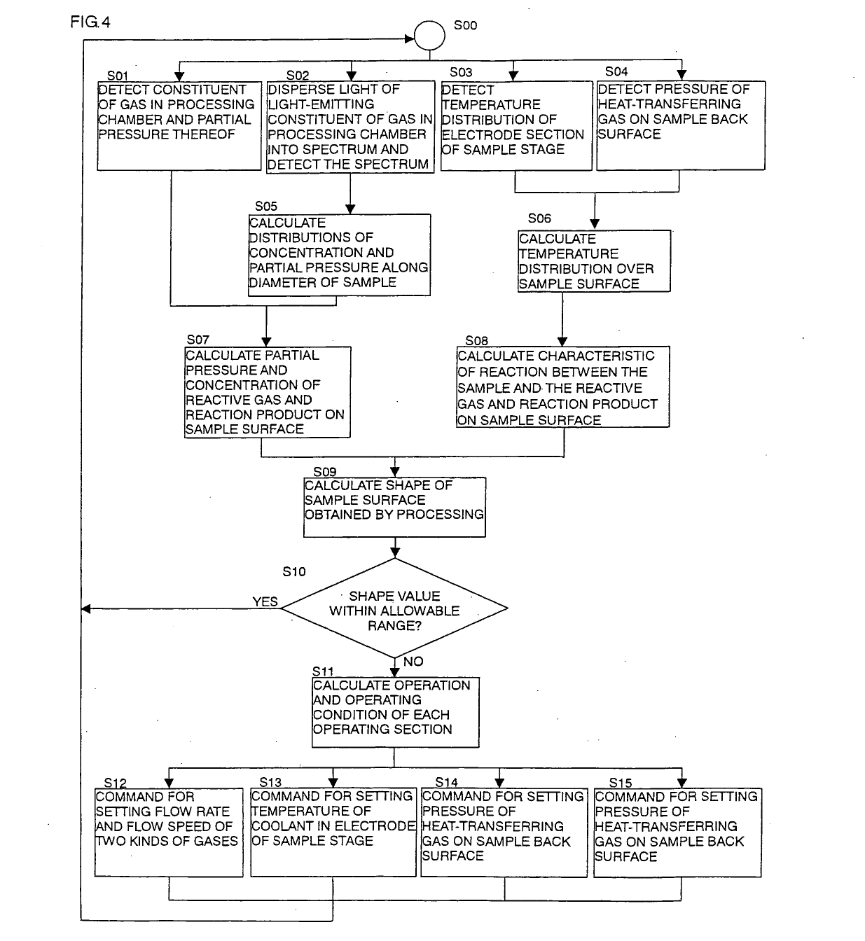

In the following, an embodiment of the present invention will be described in detail with reference to the drawings. FIG. 1 is a schematic vertical cross-sectional view of a plasma processing apparatus according to the embodiment of the present invention. FIG. 2 is a schematic enlarged vertical cross-sectional view of a sample stage, and the periphery thereof, of the plasma processing apparatus shown in FIG. 1. FIG. 3 is a schematic block diagram for illustrating an operation of the plasma processing apparatus according to this embodiment shown in FIG. 1. FIG. 4 is a flowchart illustrating an operation of the plasma processing apparatus shown in FIG. 1.

In FIG. 1, a plasma processing apparatus 100 has a vacuum vessel having a processing chamber 101 therein, produces a plasma in the processing chamber 101 and processes a sample mounted on a sample stage 102 that is disposed at a lower position in the processing chamber 101. In general, the vacuum vessel comprises: an upper vessel member including a discharge section disposed around the upper vessel member; and a lower vessel member coupled to the upper vessel member including an exhaust device connected to an lower part of the lower vessel member for evacuating or decompressing the processing chamber.

As shown in FIG. 1, the upper vessel member, which constitutes an upper part of the vacuum vessel of the plasma processing apparatus 100, comprises a lid member 103 constituting a lid of the vacuum vessel, an antenna member disposed inside the lid member 103, a magnetic field generating section 104 disposed beside and above the antenna member surrounding a discharge chamber section, and a ceiling member disposed below the antenna member. In addition, above the magnetic field generating section 104, there is provided an electric wave source section 105 that supplies an electric wave in the UHF or VHF range to the antenna member for emission. The antenna member comprises a plate-shaped antenna 106 that is made of a conductive material, such as SUS, and disposed inside the lid member 103, and at least one ring-shaped dielectric 107 that is disposed between the antenna 106 and the lid member 103 for insulating them from each other and guiding the electric wave emitted from the antenna 106 toward the ceiling member below the antenna.

In addition, the ceiling member comprises a plate 108 made of a dielectric, such as quartz, for guiding the electric wave from the antenna 106 into the processing chamber 101 below the antenna 106 (referred to as a quartz plate), and a shower plate 109 that is disposed below the quartz plate and has a plurality of holes formed therein for dispersing supplied process gas into the processing chamber.

In addition, the vacuum vessel of the plasma processing apparatus shown in FIG. 1 is detachably connected to a transfer chamber 160, and the communication between the plasma processing apparatus and the transfer chamber is opened and closed by an atmospheric gate valve 114 disposed therebetween. When the atmospheric gate valve 114 is opened, the processing chamber 101 in the vacuum vessel and the space in the transfer chamber 160 are communicated with each other and have substantially equal internal pressures. When the atmospheric gate valve 114 is opened, a wafer, which is a sample, is transferred from the transfer chamber 160 into the processing chamber and mounted on the sample stage 102 in the processing chamber.

According to this embodiment, after that the sample is mounted on the sample stage 102 is detected and confirmed, the atmospheric gate valve 114 is closed to confine the interior of the processing chamber 101 from the interior of the transfer chamber 160, and then, a processing is started with the processing chamber 101 being air tightly sealed. In the case of detaching the vacuum vessel from the transfer chamber 160 or performing maintenance of the vacuum vessel, the atmospheric gate valve 114 is closed, the internal pressure of the processing chamber 101 is raised to the atmospheric pressure, and then, outer vessel members 111 and 112 of the vacuum vessel are opened to expose the vacuum vessel to the atmosphere.

A space formed below the shower plate 109 and above the sample stage 102 constitutes a discharge chamber 150, in which a plasma is produced by interaction among the supplied process gas, the electric wave introduced through the quartz plate 108 and the magnetic field generated by the magnetic field generating section. In addition, a narrow gap space is formed between the quartz plate 108 and the shower plate 109. The process gas to be supplied to the discharge chamber 150 is first supplied to the gap space and then flows into the discharge chamber 150 through the holes in the shower plate 109 that communicate the gap space and the discharge chamber 150 with each other to allow the process gas to flow.

In other words, the gap space serves as a buffer chamber 115 that allows the process gas to be dispersed into the discharge chamber 150. The buffer chamber 115 is separated into a plurality of sub-chambers close to the center or circumference of the sample stage 102 or processing chamber 101. The process gas is supplied to the discharge chamber 150 via two process gas lines 116 and 117, process gas shut-off valves 116 and 117 disposed thereon from flow controllers 120 and 121 for controlling supply of a fluid, such as gas, to the processing chamber 101, respectively.

According to this embodiment, the gasses supplied to the processing chamber through the process gas lines 116 and 117 are different kinds of gasses supplied from different gas sources and are supplied to the processing chamber 101 through a buffer sub-chamber 115 close to the circumference of the buffer chamber and a buffer sub-chamber 115 close to the middle of the buffer chamber, respectively. That is, according to this embodiment, different kinds of gases are supplied into the processing chamber 101 at different positions through independent supply paths. Alternatively, the gasses supplied at the different positions may be mixed gases of different compositions of different kinds of constituents or mixed gasses of different compositions of same constituents.

In this way, because the process gas is dispersed into the discharge chamber 150 through the plural holes, the holes are arranged primarily in an area facing the sample mounted on the sample stage 102, and the buffer chamber 115 helps to provide more uniform dispersion of the process gas, the density of the plasma is made more uniform. In addition, inside a ring-shaped member disposed along the lower circumferences of the quartz plate 108 and the shower plate 109 below the lid member 103, there is formed a gas path communicated to the gas lines 116 and 117 to allow the process gas to flow into the buffer chamber 115.

In addition, below the shower plate 109, an upper vessel side wall 123 is disposed in contact with lower surfaces of the ring-shaped member and the shower plate 109 and facing the plasma in the vacuum vessel and defines the discharge chamber 150. In the upper vessel side wall 123, there is disposed a light-receiving section 125 that is connected to a light emission spectrometer 124, receives light produced when the plasma is produced in the processing chamber 101 and transmits the light to the light emission spectrometer 124. The light emission spectrometer 124 detects a spectrum of the light of the plasma and determines concentrations and amounts of a constituent of the plasma for various wavelengths and the distributions thereof. According to this embodiment, the light-receiving section 125 penetrates the upper vessel side wall 123. However, a window made of a translucent material, such as quartz, may be attached to the upper vessel side wall 123 to hermetically seal the processing chamber 101.

A discharge chamber base plate 126 is disposed on the outer side of the upper vessel side wall 123 in contact with a lower surface thereof. Furthermore, a lower surface of the discharge chamber base plate 126 is connected to the lower vessel including the outer vessel member 111 disposed below the discharge chamber base plate 126. Here, the upper vessel side wall 123 serves also as a ground electrode for the plasma in the discharge chamber 150 and the sample stage 102 serving as an electrode and has an area enough to stabilize the potential of the plasma.

As described above, according to this embodiment, the outer wall member constituting the lower part of the vacuum vessel can be generally separated into the upper and lower parts. The upper part is the upper outer vessel member 111 that is attached, in a fixed position by means of a bolt or the like, to the transfer chamber 160 or to a member attached to the transfer chamber 160 to constitute the transfer chamber 160. On the other hand, the lower part is the lower outer vessel member 112 that is fixedly attached, from below, to the upper outer vessel member 111 by means of a bolt or the like.

Here, one or more vessels are disposed in the outer vessel members 111 and 112 arranged vertically to constitute the outer wall of the vacuum vessel, thereby providing a multiplex chamber in which one chamber is disposed in another. According to this embodiment, there are two, inner and outer, vessels. That is, an inner vessel member 127 is disposed in the upper outer vessel member 111, and an inner vessel member 128 is disposed in the lower outer vessel member 112. That is, there are two inner vessel members 127 and 128 arranged vertically. The sample stage 102 is disposed in the inner vessel members 127 and 128, and the space in the innermost chamber constitutes the lower part of the processing chamber 101 in which the plasma is produced and from which gas and a reaction product are ejected through a space between the inner vessel members 127 and 128 and the sample stage 102.

The lower part of the processing chamber 101 is communicated with the discharge chamber 150 located above the part and, as described later, can be communicated with the space between the inner vessel members 127, 128 and the outer vessel members 111, 112, so that the lower part can be decompressed by exhaust means, and the plasma, the gas, and the reaction product in the discharge chamber 150 can be moved during processing of the sample.

In addition, the inner vessel members 127 and 128 are conductive, electrically continuous with the outer vessel members 111 and 112 and set at a predetermined potential. As described above, the inner vessel members 127 and 128 are in contact with the plasma at the inner surfaces thereof. Thus, to stabilize the processing or to stabilize the interaction with particles in the plasma, the potential of the inner vessel members 127 and 128 has to be set at a particular value. According to this embodiment, the inner vessel members 127 and 128 are grounded and set at the ground potential. Therefore, as with the upper vessel side wall 123 described above, the potential of the plasma is stabilized, and the interaction with particles in the plasma is stabilized.

For grounding, the inner vessel members 127 and 128 are made of a conductive material, and the upper or lower end of the inner vessel member 128 is electrically continuous with the outer vessel member 111 made of a conductive material. The inner vessel member 127 is coupled to, or in contact with, the upper surface of the lower outer vessel member 112, which is also made of a conductive material, at the lower surface, thereby assuring the electrical continuity therebetween. The outer vessel members 111 and 112 are connected to each other by wiring and grounded, thereby grounding the inner vessel members 127 and 128.

According to this embodiment, in order to analyze a constituent of the gas in the processing chamber at a position lower than the sample-mounting surface of the sample stage 102, there is provided a mass spectrometer 129, which is configured to take in the gas in the processing chamber 101 through a hole formed in the inner surface of the lower inner vessel member 128 and detect the constituents of the gas and the respective partial pressures. The hole is formed at a position lower than the sample-mounting surface of the sample stage 102, and the mass spectrometer 129 detects a constituent that has reacted on the sample surface or in the processing chamber above the sample along with a constituent that comes without reaction. According to this embodiment, a mass spectrometer referred to as a quadrupole mass spectrometer (Q-mass) is used, and constituents of a wide range of masses (molecular weights or atomic weights) can be detected in real time regardless of whether the constituents emit light or does not emit light. The light emission spectrometer 124 described above can detect only the constituents that emit light. However, it is known that, in actual sample processing or, in particular, in etching of a semiconductor wafer, a constituent that emits no light or a constituent of a small mass (molecular weight or atomic weight) has a significant effect on the processing. Thus, precisely detecting such a constituent allows the processing to be performed with a desired precision through precise adjustment of the operation of the apparatus.

In addition, according to this embodiment, a mass spectrometer referred to as a quadrupole mass spectrometer (Q-mass) is used. However, if the main constituent of the process gas used in the processing to be detected or the constituent having a significant effect on the processing can be detected by a gas analyzer, such as FTIR, the light emission spectrometer can be used.

The plasma processing apparatus according to this embodiment has a control device 130, which receives the results of detection by the light emission spectrometer 124 and the mass spectrometer 129 and adjusts or controls the operation of the plasma processing apparatus based on the received results or an output of a sensor that detects the condition in the processing chamber 101 or conditions of other operating sections.

The control device 130 is connected to the flow controllers 120 and 121 for the two kinds of gasses that operate to allow the plasma processing apparatus 100 to operate, the light emission spectrometer 124, the mass spectrometer 129, a coolant flow controller 131 that adjusts the supply of a heat exchange medium (coolant) circulating in the sample stage 102 and the like. Furthermore, the control device 130 is connected to the main unit of the apparatus 100 and a sensor for detecting the condition at the position via communication means, receives the output of the sensor, and outputs a command to adjust the flow rates of the two kinds of process gasses, the temperature of the sample stage 102 or the like.

In FIG. 2, the sample stage 102 and the periphery are shown enlarged. As shown in this drawing, a semiconductor wafer 201, which is a sample, is mounted on the sample stage 102. In addition, the sample stage 102 comprises an electrode block 202 that is made of a conductor and is supplied with electric power from a high-frequency power supply and a dielectric film 203 formed on the electrode block 202. The dielectric film 203 serves to insulate the semiconductor wafer 201 from the electrode block 202. In addition, the dielectric film 203 has a conductive thin film that is set at a certain potential and allows the semiconductor wafer 201 to be sucked to and held on the sample stage 102 by the electrostatic attraction between the thin film and the semiconductor wafer 201.

The electrode block 202 incorporates coolant paths 204 and 205 that allow the temperatures of the middle part and the circumference part of the sample stage 102 to be adjusted to different temperatures by coolants flowing through the respective coolant paths. The coolant paths have flow controllers 131a and 131b, respectively, and, according to this embodiment, the temperature of the coolant is adjusted or set in the flow controllers to a preferred value. The two coolant paths 204 and 205 are configured in a spiral or substantially concentric arrangement to be suited to the cylindrical sample stage 102 and are independent of each other so that the coolants therein are not mixed. The temperatures of the middle part and the circumference part of the electrode block 202 are adjusted to different temperatures by separately adjusting the coolants flowing through the coolant paths, thereby providing a temperature distribution along the radius of the circular semiconductor wafer 201 mounted on the sample stage. For example, if the circumference part of the electrode block 202 is set at a lower temperature, and the middle part thereof is set at a higher temperature, the amount of the reaction product deposited on the semiconductor wafer 201 can be reduced at the middle part, and the amount of the reaction product deposited on the semiconductor wafer 201 can be relatively increased at the circumference part.

In addition, the dielectric film 203 has recesses 206 and 207, such as grooves, formed in the middle part and in the circumference part, respectively, and a heat-transferring inert gas, such as He, is supplied to the recesses. When the semiconductor wafer 201 is mounted on the sample stage 102, the recesses 206 and 207 constitute spaces defined by the dielectric film 203 and the back surface of the semiconductor wafer 201, and the heat-transferring gas is supplied into the spaces through heat-transferring gas supply paths 210 and 211 and promotes heat transfer between the sample stage 102 and the semiconductor wafer 201. As described above, the electrode block 202 can be set at different temperatures in the middle part and the circumference part, and the semiconductor wafer 201 can have a temperature distribution reflecting the temperature distribution of the electrode block 202.

In addition, the buffer sub-chambers 115 separated for the middle part and the circumference part of the semiconductor wafer 201 are disposed between the shower plate 109 and the plate 108. The shower plate 109 has gas introduction holes 208 and 209 that communicate the buffer sub-chambers 115 with the processing chamber 101 for introducing the gas in the buffer sub-chambers 115 into the processing chamber 101. The gas introducing holes 208 and 209 are disposed close to the middle and close to the circumference, respectively. In such an arrangement, by adjusting the operations of the gas flow controllers 120 and 121 for controlling the flow rates of the gasses flowing through the process gas lines 116 and 117 associated with the gas introducing holes, the process gas introduced from gas sources 401 and 402 into the processing chamber 101 can be adjusted, and distributions of the reactive gas and the reaction product along the diameter of the semiconductor wafer 201 can be adjusted.

The light-receiving section 125 of the light emission spectrometer 124 is attached to the upper vessel side wall 123 that is in contact with the lower surface of the circumference part of the shower plate 109. According to this embodiment, one light emission spectrometer 124 having one light-receiving section 125 is used. However, a plurality of light-receiving section 125 or a plurality of light emission spectrometer 124 may be disposed along the circumference of the cylindrical upper vessel side wall 123.

The light-receiving section 125 receives light emitted in the discharge section 150 surrounded by the upper vessel side wall 123 to which it is attached. According to this embodiment, the light-receiving section detects light emission within a range of angle covering the diameter of the semiconductor wafer 201 in a substantially horizontal plane at the height of the light-receiving section. As described later, based on the spectrum of the detected light emission, a relative distribution of the concentration of a light-emitting constituent along the diameter of the semiconductor wafer 201. For the two kinds of gasses, the independent supply paths 116 and 117 and the flow controllers (MFC) 120 and 121 are provided, and the light emission detector (the light emission spectrometer 124 and the light-receiving section 125) detects the distribution of the light emission along the sample surface in the plasma producing space below the gas introducing holes.

The mass spectrometer 129 detects and analyzes the constituents of the gas below the sample stage 102 in the processing chamber, that is, the constituents of the exhaust gas, and outputs the mass spectrum of the gas (exhaust gas) as a result of the detection. As described above, the spectrum contains a constituent that emits no light or a constituent that can be detected by the light emission spectrometer 124. Therefore, the spectrum can complement the detection result of the light emission spectrometer 124, thereby enhancing the precision of detection of the constituents of the gas in the processing chamber. In addition, by appropriately using information from both the mass spectrometer 129 and the light emission spectrometer 124, distributions of the concentration and partial pressure of the reactive gas and the reaction product along the diameter of the semiconductor wafer 201 can be obtained.

The control device 130 is connected to the light emission spectrometer 124, the mass spectrometer 129, the coolant flow controllers 131a and 131b, adjustment valves 212 and 213 disposed on the heat-transferring gas supply paths 210 and 211, the flow controllers 120 and 121 on the process gas lines, and a supply power controller 214 for the high-frequency power supply connected to the electrode block 202, and transmits/receives detection results and operation commands to/from these components.

FIG. 3 is a schematic block diagram showing the control device 130. As shown in FIG. 3, the control device 130 essentially comprises a calculator 301, two internal storage units 302 and 303 and interfaces 304 and 305 connected to the calculator means 301. According to this embodiment, the control device 130 receives an output of a sensor in the plasma processing apparatus 100 via the first interface 304 and transmits an operation command to an operating section. The operation command may be one calculated by the calculator means 301.

The interface 305 is connected to the calculator means 301 and a communication path 310. The interface 305 enables the control device 130 and the calculator means 301 to communicate with, and transmit/receive data to/from, external storage units 306, 307, 308 and 309 that are connected to, and can communicate with, the interface 305 via the communication path 310. The internal storage units 302 and 303 are connected to, and can communicate with, the calculator means 301, and data or a program stored in the internal storage units is transmitted to the calculator means in response to a request from the calculator means.

According to this embodiment, the internal storage unit 302 stores a program for calculating the shape of the surface of the semiconductor wafer 201 to be processed based on information from a sensor, the light emission spectrometer 124 or the mass spectrometer 129 or detection information about the temperature of the coolant supplied to the sample stage 102 or the like or based on the result of a calculation using the these pieces of information, or stores a part of data required for the program.

According to this embodiment, as with the internal storage unit 302, the internal storage unit 303 stores a program or a part of data used with the program. In particular, the internal storage unit 303 stores: a program for calculating the amounts of operation of the flow controllers 120, 121 on the process gas lines, the flow controllers (temperature controllers) 131a, 131b for the coolants flowing in the sample stage 102, the adjustment valves 212, 213 for the heat-transferring gas and the supply power controller 214 based on the result of comparison between a predetermined value and a value representative of the resulting shape of the semiconductor wafer 201 detected using the program stored in the internal storage unit 302; and a part of data required for the program.

The external storage unit 306 stores correlation data about a correlation between a light-emitting substance constituent and a non-light-emitting substance constituent in the processing chamber 101. For example, as described above, the gas in the processing chamber 101 contains a plurality of kinds of constituents other than the light-emitting constituent. The data in the external storage unit 306 can provide distributions of the concentration and partial pressure of the non-light-emitting constituents or low-light-emitting constituents with respect to distributions of the concentration and partial pressure of the light-emitting constituent under a specific processing condition. Thus, from the distributions of the concentration and partial pressure of the light-emitting constituent over the wafer surface detected by the light emission spectrometer 124 and the distribution of the mass spectrum including the low or non-light-emitting constituents detected by the mass spectrometer 129, the distributions of the concentration and partial pressure of the reactive gas and reaction product over the surface of the semiconductor wafer 201 at a predetermined height of the light-receiving section 125 can be calculated.

The external storage unit 307 stores correlation data about a correlation between the temperature of the surface of the sample, such as the semiconductor wafer 201, and a characteristic of the reaction between a substance in the plasma, such as the reactive gas or reaction product, and the sample surface. For example, when the sample temperature is high, the reaction between some of the reaction gas and the sample surface is promoted, and the release of the reaction product from the sample surface is also promoted. Using this characteristic, the temperature distribution of the sample stage 102 can be adjusted to provide a desired temperature distribution over the surface of the semiconductor wafer 201. Thus, the progress of the reaction on the surface of the semiconductor wafer 201 can be adjusted, and thus, the processing can be adjusted so that a desired shape is obtained. If information about the distribution of the concentration or partial pressure of the reactive gas or reaction product over the semiconductor wafer 201 is obtained, the distribution of the progress of the reaction involved with the processing over the surface of the semiconductor wafer 201 can be obtained from the distribution information and the correlation data.

The external storage unit 308 stores correlation data about a correlation among the distributions of the concentration and partial pressure of the reactive gas and reaction product, the distribution of a characteristic of the reaction, and the shape resulting from the processing. Once the characteristic of the reaction on the surface of the semiconductor wafer 201 being actually processed is detected using the data in the external storage unit 307, the shape of the surface of the semiconductor wafer 201 resulting from the processing can be detected or calculated using the detection result an the correlation data in the external storage unit 308.

Since the distributions of the concentration and partial pressure of the light-emitting constituent in the processing chamber 101 detected by the light emission spectrometer 124 are the distributions of the concentration and partial pressure along the diameter of the wafer at the height of the light-receiving section 125, the distributions of the reactive gas and the reaction product obtained using the data in the external storage unit 306 are also those at the height of the light-receiving section 125. To obtain information about the distribution in the lower space in the processing chamber 201, that is, the distribution over the surface of the semiconductor wafer 201, from the information about the distribution in the upper space in the processing chamber 101, correlation data about a correlation between the distribution in the upper space and the distribution in the lower space is needed. The external storage unit 308 stores this correlation data. From the correlation data about the upper and lower distributions and the information about the upper distribution, information about the distributions of the concentration and partial pressure of the reactive gas and reaction product over the sample surface can be obtained.

The external storage unit 309 stores correlation data about a correlation between values of the flow rate, the flow speed, the composition and the like of the gas supplied to the processing chamber 101 through the two process gas lines 116 and 117 and the distributions of the concentration and partial pressure of each constituent of the reactive gas and reaction product in the plasma resulting from the supply of the gas. If shape data about the shape resulting from the processing detected or calculated using the data in the external storage unit 308 does not lie within an allowable range, the supply of the process gas, the temperature distribution of the sample stage 102, the supplied power, the pressure of the heat-transferring gas or the like has to be adjusted to appropriately adjust the distributions of the reactive gas and the reaction product over the surface of the semiconductor wafer 201 and the distribution of the reaction characteristic. The effect of the amount or volume, quantities, or the rates thereof of the supplied process gas on the distributions of the concentration and partial pressure of the reactive gas and the reaction product at a predetermined position in the processing chamber 101 depends on other plural conditions, such as the temperature in the processing chamber 101 and the electric wave, and therefore is difficult to uniquely determine. Thus, according to this embodiment, the data on the amount etc. mentioned above of the supplied process gas is stored in the external storage unit 309 in the form of correlation data.

As described above, the calculator 301 receives the data, program and algorithm stored in the internal and external storage units described above and receives outputs of sensors in the plasma processing apparatus itself via the interfaces 304 and 305. Based on the received information, the calculator 301 calculates operation commands to adjust the operations of the operating sections.

FIG. 4 is a flowchart illustrating an operation of the plasma processing apparatus 100 shown in FIG. 1. In FIG. 4, in step S00, the control device 130 sends out an operation command to each operating section of the plasma processing apparatus 100 and a command to output a detection result to each sensor in the plasma processing apparatus 100.

In step S01, the mass spectrometer 129 detects, in the form of mass spectra, the concentration and partial pressure of each constituent of the reactive gas, the reaction product and the like contained in the gas in the processing chamber 101 at a height lower than the sample mounting surface of the sample stage 102.

In step S02, the light emission spectrometer 124 receives light of a light-emitting constituent in the plasma in the discharge chamber 150 at the light-receiving section 125, disperses the light into an intensity spectrum and detects the intensity spectrum. From the spectrum, the distribution of the concentration of the light-emitting constituent in the discharge chamber 150 can be obtained. Here, since the light-receiving section 125 detects light emission within a range of angle covering the diameter of the semiconductor wafer 201 in a substantially horizontal plane at the height of the light-receiving section, the light-emitting constituent in the plasma on the wafer surface can be detected.

In step S05, from the distribution of the light-emitting constituent obtained in step S02, the distributions of the density and partial pressure thereof along the diameter of the semiconductor wafer 201 are calculated. For example, the Abel conversion is used for this calculation.

In step S03, the temperature distribution of the surface of the electrode block 202 of the sample stage 102 or the surface of the sample stage 102 is detected. For example, the temperatures of the coolants flowing through the coolant paths 204 and 205 in the electrode block 202 may be detected by the flow controllers 131a and 131b, which serve also as temperature controllers for the coolants, and the temperature of the surface of the sample stage may be determined from the detection values through an appropriate calculation.

In step S04, the pressure of the heat-transferring gas supplied to the back surface of the sample is detected. The pressure is detected by receiving outputs of pressure sensors provided on the adjustment valves 212 and 213 on the gas supply paths 210 and 211.

In step S06, from the distribution of the surface temperature of the electrode block 202 or the sample stage 102 determined in step S03 and the pressure of the heat-transferring gas determined in step S04, the temperature of the surface of the semiconductor wafer 201 is determined.

In step S07, from the mass spectra of the reactive gas and the reaction product including the low or non-light-emitting constituent determined in step S01 and the distributions of the concentration and partial pressure of the light-emitting constituent on the semiconductor wafer 201 determined in step S05, the concentration and partial pressure of each constituent of the reactive gas and the reaction product including the low or non-light-emitting constituent at a predetermined height in the processing chamber 101 and the distributions thereof are calculated. The distributions are calculated using the correlation data about the light-emitting substance constituent and the low or non-light-emitting substance constituent in the processing chamber 101 stored in the external storage unit 306.

In step S08, from the temperature distribution of the semiconductor wafer 201 determined in step S06, the distributions of a reaction characteristic (reaction factor, for example) of the reactive gas and reaction product over the surface of the semiconductor wafer 201 and the surface of the wafer are determined. This determination is accomplished using the correlation data about a correlation between the sample surface temperature and a characteristic of the reaction between the sample surface and the reactive gas and reaction product stored in the external storage unit 307.

In step S09, from the distributions of the density and partial pressure of the reactive gas and the reaction product over the surface of the sample, that is, the semiconductor wafer 201, determined in step S07 and the distribution of the reaction characteristic over the surface of the semiconductor wafer 201 determined in step S08, the shape of the surface of the semiconductor wafer 201 resulting from the processing is calculated. This calculation is accomplished using the correlation data stored in the external storage unit 308.

In step S10, it is determined whether the shape data obtained in step S09 lies within an allowable range or not. If the shape data lies within the allowable range, the process returns to step S00. On the other hand, if the shape data does not lie within the allowable range, the command sent out to each operating section has to be calculated again to adjust the operation of the plasma processing apparatus 100 so that a desired shape falling within the allowable range can be obtained.

In step S11, a required operating condition of the plasma processing apparatus 100 is calculated, and an operating condition of each operating section is calculated. In steps S12 to S15, commands for setting the flow rate and flow speed of the two kinds of gases, a command for setting the value of the temperature of the coolant flowing through the electrode block 202 of the sample stage 102, a command for setting the pressure value of the heat-transferring gas supplied to the back surface of the semiconductor wafer 201, and a command for setting the value of the power supplied from the high-frequency power supply to the electrode block 202 of the sample stage 102 are issued to the corresponding operating sections, respectively. For example, commands are issued to the flow controllers 120 and 121 on the process gas lines 116 and 117, the coolant flow controllers 131a and 131b, the adjustment valves 212 and 213 on the supply paths for the heat-transferring gas, or the supply power controller 214, such as a variable capacitor, disposed between the high-frequency power supply and the electrode block 202. Then, the process returns to step S00.

With such an arrangement according to this embodiment described above, of the reactive gas and the reaction product involved in the processing of the semiconductor wafer, distributions of the density and partial pressure of constituents of a wide range of masses, molecular weights or atomic weights including anon-light-emitting constituent can be determined, and the operation of the plasma processing apparatus can be appropriately adjusted through adjustment of the operating sections thereof based on the determined distributions. Therefore, the semiconductor wafer can be processed with high precision.

In addition, since distributions of density over the surface of the semiconductor wafer are determined using the spectrum of the light of the light-emitting constituent in the processing chamber and the distribution of the low or non-light-emitting constituent described above, the processing condition of the semiconductor wafer surface can be detected over a wide area. Besides, since operations and operating conditions of operating sections of the apparatus is adjusted based on the result of the detection, the processing can be accomplished with a higher precision. Furthermore, since the temperature distribution over the semiconductor wafer surface is detected, the distribution of a reaction characteristic over the surface is derived from the temperature distribution, the shape resulting from the processing is detected using the distribution of the reaction characteristic, and the operations and the operating conditions described above are adjusted or controlled based on the detected shape, the processing can be accomplished with a still higher precision.

In addition, since at least two kinds of gasses are supplied to the processing chamber, and the supply of at least two kinds of gasses is adjusted based on the detected processing condition and the detected shape resulting from the processing, the precision of the processing is further improved.

What is claimed is:

1. A plasma processing apparatus having a processing chamber to be decompressed, a sample stage which is disposed in the processing chamber and on which a sample to be processed is mounted, and a supply hole for supplying a process gas into the processing chamber from above the sample stage and processes the sample using a plasma produced from the process gas in the processing chamber, the plasma processing apparatus comprising:
a light emission spectrometer that receives light emission of the plasma and detects a constituent of the plasma;
a mass spectrometer that takes in a gas in the processing chamber and determines the mass of a constituent of the gas; and
a control device that adjusts the operation of the plasma processing apparatus based on the output of the light emission spectrometer and the output of the mass spectrometer.

2. The plasma processing apparatus according to claim 1, wherein the control device adjusts at least one of the supply of the process gas into said processing chamber, the temperature of a coolant supplied into the sample stage, the pressure of a heat-transferring gas supplied between the sample and the sample stage, and the power supplied to an electrode provided on the sample stage.

3. A plasma processing apparatus having a processing chamber to be decompressed, a sample stage which is disposed in the processing chamber and on which a sample to be processed is mounted, a plate disposed above the sample stage, and two supply holes formed in the plate at positions close to the middle and the circumference of the processing chamber for supplying different kinds of process gases into the processing chamber and processes the sample using a plasma produced from the process gases in the processing chamber, the plasma processing apparatus comprising:
a light emission spectrometer that receives light emission of the plasma and detects a constituent of the plasma;
a mass spectrometer that takes in a gas in the processing chamber and determines the mass of a constituent of the gas; and
a control device that adjusts the supply of the process gases through the two supply holes based on the output of the light emission spectrometer and the output of the mass spectrometer.

4. A plasma processing method for processing a sample by mounting the sample to be processed on a sample stage disposed in a processing chamber to be decompressed, supplying a process gas into the processing chamber, and producing a plasma in the processing chamber, the plasma processing method comprising:
a step of adjusting the processing of the sample based on a result of receiving light emission of the plasma and detecting a light-emitting constituent of the plasma and a result of taking in a gas in the processing chamber and determining the mass of a constituent of the gas.

5. The plasma processing method according to claim 4, further comprising:
a step of determining the distribution of the constituent of the plasma over the surface of the sample based on the result of the detection of the light-emitting constituent of the plasma and the result of the determination of the mass of the constituent of the gas in the processing chamber; and
a step of adjusting the processing of the sample based on the detected distribution.

6. The plasma processing method according to claim 4, wherein the processing of the sample is adjusted by adjusting at least one of the supply of the process gas into the processing chamber, the temperature of a coolant supplied into the sample stage, the pressure of a heat-transferring gas supplied between the sample and the sample stage, and the power supplied to an electrode provided on said sample stage.

7. The plasma processing method according to claim 4, further comprising:
a step of determining the distribution of the constituent of the plasma over the surface of the sample based on the result of the detection of the light-emitting constituent of the plasma and the result of the determination of the mass of the constituent of the gas in the processing chamber; and
a step of adjusting the processing of the sample based on the detected distribution;
wherein the processing of the sample is adjusted by adjusting at least one of the supply of the process gas into the processing chamber, the temperature of a coolant supplied into the sample stage, the pressure of a heat-transferring gas supplied between the sample and the sample stage, and the power supplied to an electrode provided on said sample stage.

8. The plasma processing method according to claim 4, wherein different kinds of process gases are supplied into the processing chamber from above the sample stage at positions close to the middle and the circumference, and producing a plasma in the processing chamber, further comprising:
a step of, based on a result of receiving light emission of the plasma and detecting a light-emitting constituent of the plasma and a result of taking in a gas in the processing chamber and determining the mass of a constituent of the gas, determining the distribution of the constituent of the plasma over the surface of the sample; and
a step of adjusting the supply of the different kinds of process gases into the processing chamber.
